(19) United States
(12) Patent Application Publication
(10) Pub. No.: US 2026/0182284 A1
(43) Pub. Date: Jun. 25, 2026

(54) SEMICONDUCTOR MANUFACTURING EQUIPMENT AND SUBSTRATE PROCESSING METHOD USING SAME

(71) Applicant: SEMES CO., LTD., Cheonan-si (KR)

(72) Inventors: Jin Hee HONG, Cheonan-si (KR); Yu Jung PARK, Cheonan-si (KR); Eun Mi KIM, Cheonan-si (KR); Young Eun JEON, Cheonan-si (KR); Cheng Bin CUI, Cheonan-si (KR)

(73) Assignee: SEMES CO., LTD., Cheonan-si (KR)

(21) Appl. No.: 19/428,120

(22) Filed: Dec. 20, 2025

(30) Foreign Application Priority Data
Dec. 23, 2024 (KR) 10-2024-0194057

(51) Int. Cl. H10P 50/28; H01J 37/32; H10P 72/00

(52) U.S. Cl. CPC H10P 50/285; H01J 37/3244; H01J 37/32522; H01J 37/32724; H10P 72/0421; H01J 2237/002; H01J 2237/334

(57) ABSTRACT

Disclosed relates to semiconductor manufacturing equipment and a substrate processing method using the same and, for a method of atomic layer-based etching a metal oxide film formed on a substrate, the method includes supplying halogen-based modified gas into a processing space of a chamber where the substrate is disposed, and modifying the metal oxide film, supplying adsorbed gas into the processing space and allowing the adsorbed gas to be adsorbed on a surface of the modified metal oxide film, and supplying heat to the substrate on which the adsorbed gas is adsorbed, and etching the metal oxide film, and the modified gas is bromine-based gas or chloride-based gas, and the adsorbed gas is a β-diketone-based precursor.

### CROSS REFERENCE TO RELATED APPLICATION

The present application claims priority to Korean Patent Application No. 10-2024-0194057, filed Dec. 23, 2024, the entire contents of which are incorporated herein for all purposes by this reference.

### BACKGROUND OF THE INVENTION

### Field of the Invention

The present disclosure relates to semiconductor manufacturing equipment and a substrate processing method using the same. More specifically, the present disclosure relates to a substrate processing method configured to atomic layer-based etch a metal oxide film using halogen-based gas, β-diketone-based precursor, and heat.

### Description of the Related Art

Metal oxide films used in the high-k metal gate (HKMG) technique may be used for not only memory devices, but also logic devices.

In order to etch the metal oxide film, conventionally, the metal oxide film is modified using fluorine-based gas in gaseous state or plasma, and the modified metal oxide film is etched using a metal precursor.

However, when an atom layer-based etching process is performed using fluorine-based gas in a gaseous state or a plasma-ionized state, fluorine ions penetrate deeply into the metal oxide film over a thickness of atom layer-based etching and break the binding, thereby generating oxygen vacancies in the metal oxide film. Furthermore, the metal oxide film modified using fluorine-based gas is not completely removed after the atom layer-based etching process is finished and remains partially to generate oxygen vacancy. The mobility of free electrons is increased or decreased sharply depending on the degree of oxygen vacancy formation, thereby acting as a factor that deteriorates the desired electrical characteristics of semiconductor devices.

Furthermore, a metal precursor generates caustic byproducts after etching the modified metal oxide film, thereby causing a polluted substrate and reducing the life cycle of devices.

### SUMMARY OF THE INVENTION

Accordingly, the present disclosure has been made keeping in mind the above problems occurring in the related art, and the present disclosure is intended to propose a substrate processing method to etch a metal oxide film without using fluorine-containing gas and a metal precursor.

The objective of the present disclosure is not limited to the above description, and other objectives and advantages not mentioned will be clearly understood by those skilled in the art from the subsequent description.

According to an embodiment of the present disclosure, there is provided a method for atomic layer-based etching a metal oxide film formed on a substrate, and the method includes: supplying halogen-based modified gas into a processing space of a chamber where the substrate is disposed, and modifying the metal oxide film; supplying adsorbed gas into the processing space and allowing the adsorbed gas to be adsorbed on a surface of the modified metal oxide film; and supplying heat to the substrate on which the adsorbed gas is adsorbed, and etching the metal oxide film, wherein the modified gas may be bromine-based gas or chloride-based gas, and the adsorbed gas may be a β-diketone-based precursor.

According to the embodiment, a cycle including the modifying of a metal oxide film or the etching of a metal oxide film may be repeated at least one time.

According to the embodiment, the metal oxide film may be one of a group consisting of HfO2, ZrO2, Bao, TiO2, Ta2O5, La2O3, HZO, and IGZO.

According to the embodiment, the modified gas may be one or a group consisting of HBr, Br2, BBr3, SiBr4, CBr4, CBr2Cl2, CBrCl3, SiCl4, CCl4, Cl2, and SiH2Cl2.

According to the embodiment, as the metal oxide film is modified using the modified gas, oxygen vacancies generated in the metal oxide film may be reduced in comparison to usage of fluorine-containing modified gas.

According to the embodiment, the β-diketone-based precursor may be one of a group consisting of Hfac, Tfac, and acac.

According to the embodiment, the usage of the β-diketone-based precursor may prevent caustic byproducts from being generated in the chamber.

According to the embodiment, the modifying of a metal oxide film and the adsorbing of adsorbed gas on a metal oxide film may be performed at a temperature ranging from −20° C. to 150° C.

According to the embodiment, the etching of a metal oxide film may be performed at a temperature ranging from 300° C. to 450° C.

According to an embodiment of the present disclosure, there is provided semiconductor manufacturing equipment, and the semiconductor manufacturing equipment includes: an index block in which a substrate is stored; a processing block including a first chamber and a second chamber to perform a process of processing the substrate; a substrate transfer block including a substrate transfer robot that is used to remove or insert the substrate; and a control device, wherein the first chamber may be a space where a metal oxide film is modified with modified gas, and adsorbed gas is adsorbed on the modified metal oxide film, and the second chamber may be a space where heat is supplied so as to atomic layer-based etch the metal oxide film on which the adsorbed gas is adsorbed.

According to the embodiment, the first chamber may include: a substrate support unit for supporting the substrate; and a gas supply unit for supplying the modified gas and the adsorbed gas to a processing space of the first chamber, wherein the modified gas may be bromine-based gas or chloride-based gas, and be supplied to modify the metal oxide film formed on the substrate, and the adsorbed gas may be a β-diketone-based precursor, and be supplied to be adsorbed on a surface of the modified metal oxide film.

According to the embodiment, the modified gas may be one of a group consisting of HBr, Br2, BBr3, SiBr4, CBr4, CBr2Cl2, CBrCl3, SiCl4, CCl4, Cl2, and SiH2Cl2.

According to the embodiment, the adsorbed gas may be one of a group consisting of Hfac, Tfac, and acac.

According to the embodiment, the first chamber may include a plasma generation unit to generate plasma in the first chamber.

According to the embodiment, the substrate support unit may include a cooling member for lower the temperature of the substrate, and the cooling member may lower the temperature of the substrate to −20° C.

According to the embodiment, the second chamber may include: a substrate support unit for supporting the substrate; a gas supply unit for supplying gas to a processing space of the second chamber; and a heating unit for supplying heat to the substrate, and wherein the heating unit may be used to etch the substrate on which the adsorbed gas is adsorbed on the surface of the modified metal oxide film.

According to the embodiment, the heating unit may be one of a group consisting of a halogen lamp, a microwave unit, a laser unit, and an infrared lamp.

According to the embodiment, the heating unit may supply heat to the processing space of the second chamber and heat the substrate to a temperature ranging from 300° C. to 450° C., thereby atomic layer-based etching the substrate on which the adsorbed gas is adsorbed on the surface of the modified metal oxide film.

According to the embodiment of the present disclosure, there is provided semiconductor manufacturing equipment including: an index block in which a substrate is stored; a processing block including a first chamber and a second chamber to perform a process of processing the substrate; a substrate transfer block including a substrate transfer robot that is used to remove or insert the substrate; and a control device, wherein the first chamber may include: a substrate support unit for supporting the substrate; a gas supply unit for supplying modified gas and adsorbed gas into a processing space of the first chamber; and a plasma generation unit for plasma-ionizing the supplied modified gas, wherein the modified gas may be bromine-based gas or chloride-based gas, and modifying of a metal oxide film may be performed by supplying the modified gas to modify the metal oxide film formed on the substrate, and the adsorbed gas may be a β-diketone-based precursor, and adsorbing of adsorbed gas may be performed by supplying the adsorbed gas so that the adsorbed gas may be adsorbed on a surface of the modified metal oxide film, the second chamber may include: a substrate support unit for supporting the substrate; a gas supply unit for supplying gas to a processing space of the second chamber; and a heating unit for supplying heat to the substrate, and atomic layer-based etching of the substrate on which the adsorbed gas is adsorbed on the surface of the modified metal oxide film may be performed by supplying heat to the substrate using the heating unit, and the modifying of a metal oxide film and adsorbing of adsorbed gas may be performed at a temperature ranging from −20° C. to 150° C., and the etching of a substrate may be performed at a temperature ranging from 300° C. to 450° C.

According to the embodiment, the control device may be configured to control the plasma generation unit, and the gas supply unit and the heating unit which may be included in the first chamber and the second chamber so as to modify the metal oxide film in the first chamber, allow a precursor to be adsorbed on the surface of the modified metal oxide film, and atomic layer-based etch the substrate on which the precursor is adsorbed on the surface of the metal oxide film modified in the second chamber.

According to the present disclosure, in order to etch the metal oxide film, bromine-based gas and chloride-based gas are used to modify the surface of the metal oxide film, and β-diketone-based precursor is adsorbed on the surface of the modified metal oxide film. Thereafter, heat is supplied to etch the metal oxide film on which the precursor is adsorbed.

The metal oxide film is modified using bromine-based gas and chloride-based gas, thereby preventing oxygen vacancy from being generated in the metal oxide film and improving the electrical characteristics of semiconductor devices.

Furthermore, β-diketone-based precursor is adsorbed on the surface of the modified metal oxide film, and then heat is applied to the metal oxide film to etch the metal oxide film on which the precursor is adsorbed, thereby preventing caustic byproducts from being generated.

Accordingly, the substrate and the chamber are not polluted, thereby improving the manufacturing yield of semiconductor devices.

The effect of the present disclosure is not limited to the above description, and other effects not mentioned will be clearly understood by those skilled in the art from the subsequent description.

### BRIEF DESCRIPTION OF THE DRAWINGS

FIG. 1 is a view showing semiconductor manufacturing equipment according to an embodiment of the present disclosure.

FIG. 2 is a view showing a first chamber according to the embodiment of the present disclosure.

FIG. 3 is a view showing a second chamber according to the embodiment of the present disclosure.

FIG. 4 is a flowchart showing a substrate processing method according to an embodiment of the present disclosure.

FIG. 5 is a concept view showing the substrate processing method according to the embodiment of the present disclosure.

FIG. 6 is a view showing the thermodynamic analysis result at temperatures during a modifying step according to the embodiment of the present disclosure.

FIGS. 7a and 7b are views showing the thermodynamic analysis result of the precursor reaction at temperatures.

FIGS. 8a and 8b are views showing the density of modified gas detected from the inside portion of a substrate.

### DETAILED DESCRIPTION OF THE DISCLOSURE

Hereinbelow, exemplary embodiments of the present disclosure will be described in detail which reference to the accompanying drawings such that the present disclosure can be easily embodied by one of ordinary skill in the art to which the present disclosure belongs. However, the present disclosure may be changed to various embodiments and the scope and spirit of the present disclosure are not limited to the embodiments described hereinbelow.

In describing the embodiment of the present disclosure, when the functions and conventional elements and the detailed description of elements related with the present disclosure may make the gist of the present disclosure unclear, a detailed description of those elements will be omitted, and the same reference numerals will be used throughout the drawings and the description to refer to the same or like elements or parts.

At least some of the terms used in the specification may be defined in consideration of functions thereof in the present disclosure, which may be varied according to the intention of a user, practice, or the like, so that the terms should be defined based on the contents of this specification.

As used herein, the singular forms “a”, “an”, and “the”, are intended to include the plural forms as well, unless the context clearly indicates otherwise. Unless the context clearly indicates otherwise, it will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Meanwhile, it should be understood that the shape or size of the elements, thickness of line, etc. shown in the drawings may be exaggeratedly drawn to provide an easily understood description of the structure of the present disclosure.

Hereinbelow, exemplary embodiments of the present disclosure will be described in detail, and in the description with reference to the accompanying drawings, the same or corresponding components regardless of reference numerals are given the same reference numerals, and duplicate descriptions thereof will be omitted.

According to an embodiment of the present disclosure, a substrate W may be a substrate formed such that a metal oxide film is formed on a silicone substrate. At this point, the metal oxide film may be one of a group consisting of HfO2, ZrO2, Bao, TiO2, Ta2O5, La2O3, HZO, and IGZO.

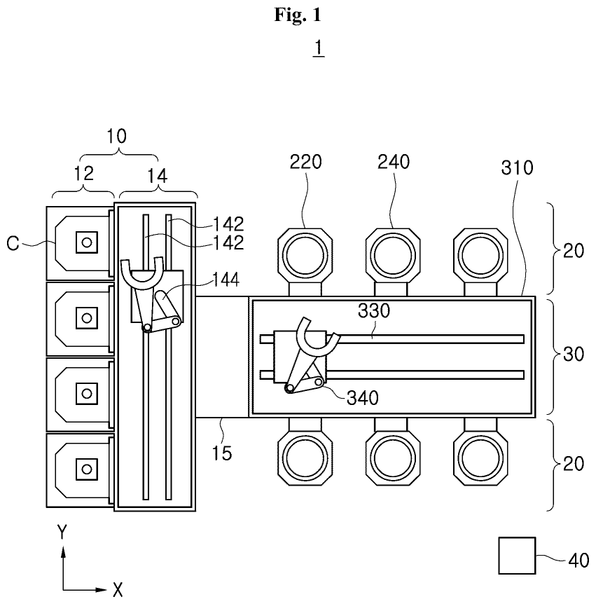

FIG. 1 is a view showing semiconductor manufacturing equipment according to an embodiment of the present disclosure.

Referring to FIG. 1, a semiconductor manufacturing equipment 1 may include an index block 10, a processing block 20, a substrate transfer block 30 transferring a substrate between the index block 10 and the processing block 20, and a control device 40. According to the embodiment of the present disclosure, the index block 10 and the processing block 20 may be disposed successively in a line.

The index block 10 includes a load port 12 on which a carrier C storing a substrate is seated, and an index frame 14 removing the substrate from the carrier C seated on the load port 12 or inserting the substrate, which has been completed in the processing, into the carrier C. The load port 12 is located at a position opposite to the processing block 20, with the index frame 14 located therebetween. A plurality of carriers C may be placed in the load port 12 and store substrates therein.

An index robot 144 may be provided in the index frame 14. The index robot 144 may be provided to be movable along a rail 142. The index robot 144 may receive a substrate from the carrier C and deliver the substrate to a load lock chamber 15, where the substrate is temporarily stored, and may receive a substrate temporarily stored in the load lock chamber 15 and deliver the substrate to the inner space of the carrier C.

The processing block 20 is a device where processing for the substrate is performed, and may include one or more plasma devices 220 and heating devices 240. According to the embodiment of the present disclosure, a first chamber 220 is a space where a modifying process is performed by supplying modified gas to a substrate to modify the substrate and an adsorbing process is performed such that a precursor is adsorbed on the modified substrate, and a second chamber 240 may be a space where an etching process is performed by etching the metal oxide film on which the precursor is adsorbed.

The substrate transfer block 30 is disposed adjacent to the processing block 20, and may receive a substrate from the load lock chamber 15 and transfer the substrate to the processing block 20 or deliver a substrate completed in the process in the processing block 20 to the load lock chamber 15. The substrate transfer block 30 may include a rail 330 arranged in an arrangement direction of a processing device 200, a substrate and transfer robot £340 transferring the substrate while being moved along the rail 330. The substrate transfer robot 340 may transfer a substrate while being moved within the internal space of a transfer chamber 310.

The control device 40 may integrally control operation of the semiconductor manufacturing equipment 1 configured as described above. The control device 40 may be, for example, a computer, and may include a central process unit (CPU), a random access memory (RAM), a read-only memory (ROM), an auxiliary memory, etc. The CPU is operated based on a program stored in the ROM or the auxiliary memory, or process conditions, and may control the entire operation of the semiconductor manufacturing equipment 1. Furthermore, a program that is readable by a computer required for control may be stored in a storage medium. The storage medium may consist of, for example, a flexible disk, a compact disc (CD), a CD-ROM, a hard disk, a flash memory, a digital video disk (DVD), or the like. The control device 40 may be located inside the equipment 1 or outside of the equipment 1. When the control device 40 is located outside of the equipment 1, the control device 40 may control the equipment 1 with a wired or wireless communication means.

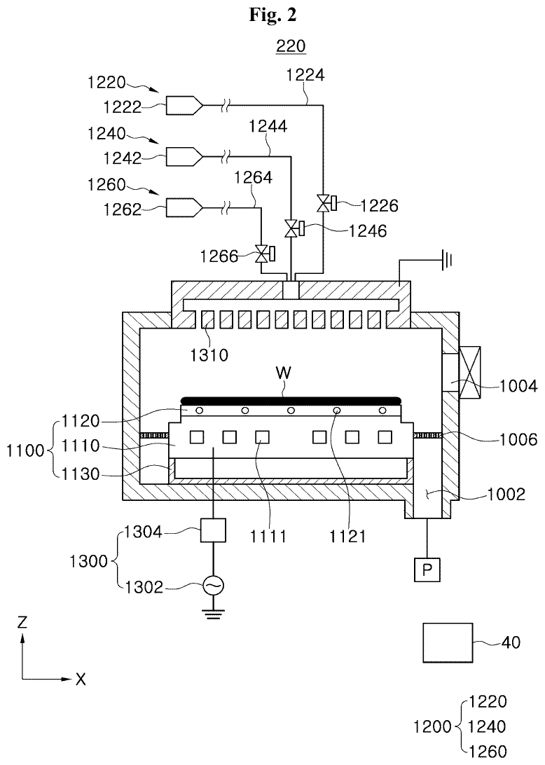

FIG. 2 is a view showing a first chamber according to the embodiment of the present disclosure.

Referring to FIG. 2, the first chamber 220 may include a substrate support unit 1100, a gas supply unit 1200, and a plasma generation unit 1300.

The first chamber 220 may include a processing space where the process is performed. The chamber 220 may include an exhaust port 1002 at a lower portion thereof, and the exhaust port 1002 may be connected to an exhaust line to which a pump P is mounted. The exhaust port 1002 may discharge byproducts generated in the process and gas remaining in the chamber 220 outside of the chamber 220 through the exhaust line. In this case, the pressure of the internal space of the chamber 220 may be reduced to a predetermined pressure.

The first chamber 220 may have an opening 1004 formed on a side wall thereof. The opening 1004 may serve as a passage through which the substrate W enters the inner space of the chamber 220. The opening 1004 may be configured to be opened and closed by a door assembly.

The baffle unit 1006 may serve to discharge plasma process byproducts, unreacted gas, etc. The baffle unit 1006 may be installed between an inner wall of a chamber 1000 and the substrate support unit 1100, which will be described below. The baffle unit 1006 may have a ring-shaped form, and has a plurality of through holes that are formed vertically through the baffle unit. A flow of process gas may be controlled depending on the number and size of the through holes of the baffle unit 1006.

The substrate support unit 1100 may be disposed in a lower region inside the chamber 220. The substrate support unit 1100 may support the substrate W by an electrostatic force. However, the embodiment of the present disclosure is not limited thereto, and various methods such as mechanical clamping, vacuum, etc. may be used to support the substrate W.

The substrate support unit 1100 may include a support body 1110 and an electrostatic chuck 1120 disposed at an upper portion of the support body 1110. The electrostatic chuck 1120 may be configured to electrostatically adsorb the substrate W and include a ceramic layer with an electrode interposed therein.

The inner space of the substrate support unit 1100 may include a heating member 1121 and a cooling member 1111 that maintain the substrate W at a process temperature. The heating member 1121 may be a heating coil. The cooling member 1111 may be a cooling line in which refrigerant flows. According to the present disclosure, the process may be performed while the substrate W is adjusted a temperature ranging from −20° C. to 150° C.

A lower portion of the support body 1110 may include a support member 1130 that supports the support body 1110 and the electrostatic chuck 1120. The support member 1130 has a cylindrical form with a predetermined height and has an internal space.

The gas supply unit 1200 may supply gas, which is required for the process, to the chamber 220. According to the embodiment of the present disclosure, the gas supply unit 1200 may include a first gas supply unit 1220, a second gas supply unit 1240, and a third gas supply unit 1260.

Each gas supply unit 1220, 1240, 1260 may include a gas supply source 1222, 1242, 1262, a gas supply line 1224, 1244, 1264, and a gas supply nozzle. The gas supply line 1224, 1244, 1264 may connect the gas supply source 1222, 1242, 1262 and the gas supply nozzle to each other. The gas supply line 1224, 1244, 1264 may supply gas stored in the gas supply source 1222, 1242, 1262 to the gas supply nozzle. The gas supply line 1224, 1244, 1264 may include a valve 1226, 1246, 1266 to open or close the passage or adjust the flow amount of a fluid flowing through the passage.

The first gas supply unit 1220 may include the gas supply source 1222, the gas supply line 1224 to supply gas into the internal space of the chamber 220. The gas supply line 1224 may include the gas valve 1226 to adjust the flow amount of supplied gas. According to the embodiment of the present disclosure, gas supplied from the first gas supply unit 1220 is modified gas, and may be a halogen-based gas. Specifically, the modified gas may be bromine-based gas and chloride-based gas. For example, the modified gas may be one of a group consisting of HBr, Br2, BBr3, SiBr4, CBr4, CBr2Cl2, CBrCl3, SiCl4, CCl4, Cl2, and SiH2Cl2.

The second gas supply unit 1240 may include the gas supply source 1242 and the gas supply line 1244 to supply gas into the internal space of the chamber 220. The gas supply line 1244 may include the gas valve 1246 to adjust the flow amount of supplied gas. According to the embodiment of the present disclosure, gas supplied from the second gas supply unit 1240 is adsorbed gas, and may be a β-diketone-based precursor. The β-diketone-based precursor may be one of a group consisting of Hfac (hexafluoroacetylacetone), Tfac (trifluoroacetyl chloride), and acac (acetylacetone), but is not limited thereto.

The third gas supply unit 1260 may include the gas supply source 1262 and the gas supply line 1264 to supply gas into the internal space of the chamber 220. The gas supply line 1264 may include the gas valve 1246 to adjust the flow amount of supplied gas. According to the embodiment of the present disclosure, gas supplied from the third gas supply unit 1260 is purging gas, and may be inert gas such as argon (Ar), helium (He), nitrogen (N2), etc. The purging gas may be supplied to the chamber 220 after the modified gas supply and the adsorbed gas supply are stopped.

The plasma generation unit 1300 may generate plasma into the processing space of the chamber 220. Plasma may be formed in an upper region of the substrate support unit 1100 in the chamber 220. According to the embodiment of the present disclosure, the plasma generation unit 1300 generates plasma in the processing space of the chamber 220 using a capacitively coupled plasma (CCP) source.

However, the embodiment is not limited thereto. The plasma generation unit 1300 is capable of generating plasma in the processing space of the chamber 220 by using different types of plasma sources, such as an inductively coupled plasma (ICP) source, a microwave plasma source, or the like.

The plasma generation unit 1300 may include a high frequency power source 1302 and a matching device 1304. The high frequency power source 1302 may supply high frequency power to one of an upper electrode and a lower electrode to generate potential difference between the upper electrode and the lower electrode. Herein, the upper electrode may be a shower head 1310, and the lower electrode may be the substrate support unit 1100. The high frequency power source 1302 is connected to the lower electrode, and the upper electrode may be grounded.

The shower head 1310 may be formed to vertically face the substrate support unit 1100 inside the chamber 220. The shower head 1310 may include a plurality of gas spraying holes to evenly spray gas into the chamber 220. Meanwhile, the shower head 1310 may be made of a material with a silicone component, and it is possible to use a material with a metal component.

According to the embodiment of the present disclosure, the control device 40 may supply the modified gas and the adsorbed gas into the processing space in the chamber 220 in order to perform a modifying step and an adsorbing step, which will be described below. At this point, the control device 40 may control the heating member 1121 and the cooling member 1111 of the substrate support unit 1100 to adjust the temperature of the substrate W within a range from −20° C. to 150° C. The control device 40 may control a supplied form of the modified gas supplied from the first gas supply unit 1220 into a gaseous state or a plasma state, depending on a type of the metal oxide film. Furthermore, the control device 40 may control the substrate W so that the substrate W, in which the adsorbed gas is adsorbed on the surface of the metal oxide film modified in the first chamber 220, is moved to the second chamber 240. The substrate transfer block 30 may maintain a vacuum state during the movement of the substrate W from the first chamber 220 to the second chamber 240.

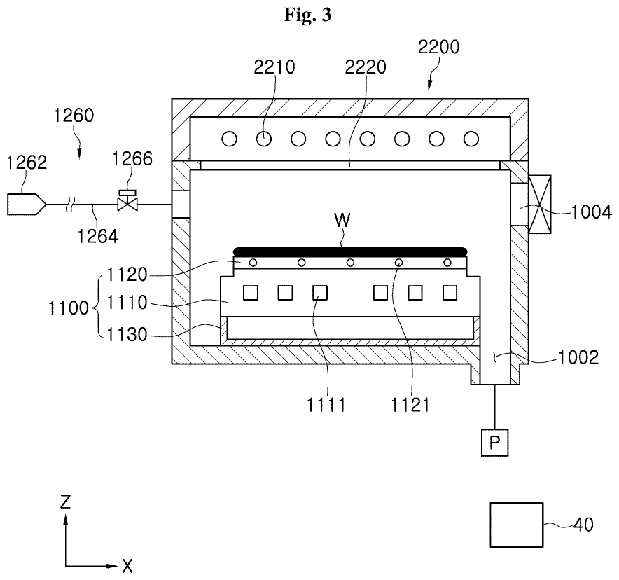

FIG. 3 is a view showing a second chamber according to the embodiment of the present disclosure.

Referring to FIG. 3, in the second chamber 240, the etching process is performed using a heating unit 2200 without using plasma, as used in the first chamber 220 in FIG. 2, which is different from the first chamber 220 in FIG. 2.

Referring to FIG. 3, the second chamber 240 may include the heating unit 2200 to supply heat to the metal oxide film on which the precursor is adsorbed and to atomic layer-based etch the metal oxide film.

The heating unit 2200 may include a plurality of heating lamps 2210 that generate thermal energy, and supply heat to the substrate W that is located at a lower space while facing the heating unit.

A window 2220 may be formed between the heating lamps 2210 and the substrate support unit 1100. The window 2220 may serve as a protector that prevents etching byproducts generated when the process progresses from being deposited on the heating lamps 2210. For example, the window 2220 may be a dielectric window. The window 2220 may transmit optical wavelengths generated from the heating lamps 2210 to supply heat to the substrate W. According to the present disclosure, the heating unit 2200 is used to supply heat so that the temperature of the substrate W is adjusted to a temperature ranging from 300° C. to 450° C., thereby atomic layer-based etching the substrate W in which the precursor is adsorbed on the surface of the modified metal oxide film.

According to the embodiment of the present disclosure, the control device 40 may supply heat into the processing space of the chamber 240 to perform an etching step, which will be described below. At this point, the control device 40 may control the heating unit 2200 to supply heat so that the substrate W has a temperature ranging from 300° C. to 450° C. Furthermore, the control device 40 may control the heating unit 2200 so that the heating unit 2200 supplies heat to the substrate W and simultaneously supplies inert gas.

According to the present disclosure, it is illustrated that the first chamber 220 is used to modify the metal oxide film and allows the precursor to be adsorbed on the surface of the metal oxide film, and the second chamber 240 is used to etch the metal oxide film on which the precursor is adsorbed, but the present disclosure is not limited thereto. For example, a single chamber is used to modify the metal oxide film, allow the precursor to be adsorbed on the surface of the modified metal oxide film, and etch the metal oxide film with supplied heat. In this case, all the gas supply unit, the plasma generation unit, and the heating unit may be provided in a single chamber.

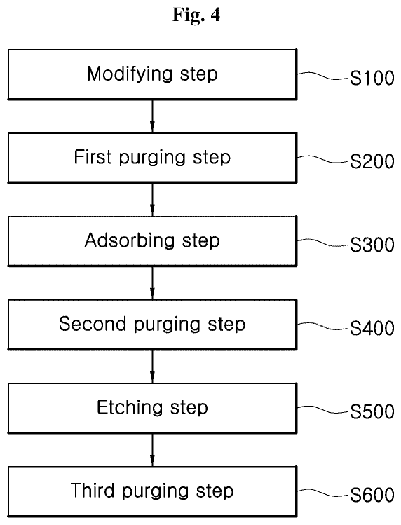

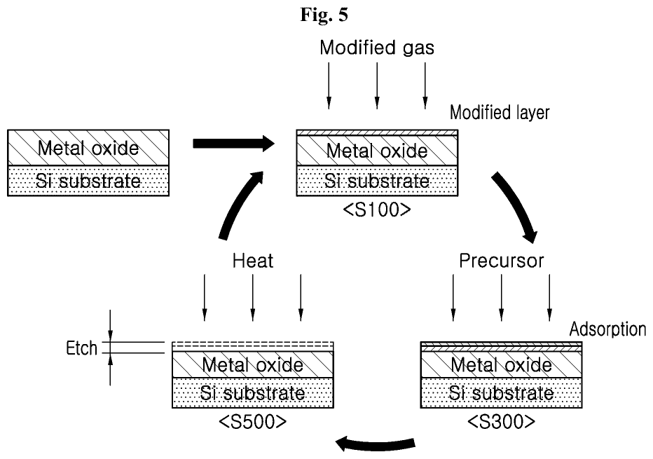

FIG. 4 is a flowchart showing a substrate processing method according to an embodiment of the present disclosure. FIG. 5 is a concept view showing the substrate processing method according to the embodiment of the present disclosure. The substrate processing method of the present disclosure uses the semiconductor manufacturing equipment shown in FIGS. 1 to 3, so the method will be described with reference to FIGS. 1 to 5.

Referring to FIGS. 1 to 5, the method for atomic layer-based etching the metal oxide film formed on the substrate is performed by: a modifying step performed by supplying the halogen-based modified gas into the processing space of the chamber with the substrate disposed and modifying the metal oxide film, S100; a primary purging step performed by supplying the purging gas into the processing space and removing the modified gas remaining in the processing space, S200; an adsorbing step performed by supplying the adsorbed gas into the processing space and allowing the adsorbed gas to be adsorbed on the modified metal oxide film, S300; a secondary purging step performed by supplying the purging gas into the processing space and removing the adsorbed gas remaining in the processing space, S400; an etching step performed by supplying heat to the substrate on which the adsorbed gas is adsorbed and etching the metal oxide film, S500; and a third purging step performed by supplying the purging gas into the processing space and removing etching byproducts, S600. One cycle including the modifying step to the third purging step S100 to S600 is performed, and at least one cycle is repeated so that the metal oxide film formed on the substrate may be etched into a desired thickness.

The modifying step S100 may be performed by supplying the modified gas from the first gas supply unit 1220 into the processing space of the first chamber 220 where the substrate W is disposed and modifying the metal oxide film. According to the embodiment of the present disclosure, the modified gas is halogen-based gas, and may be bromine-based gas or chloride-based gas. For example, the modified gas may be one of a group consisting of HBr, Br2, BBr3, SiBr4, CBr4, CBr2Cl2, CBrCl3, SiCl4, CCl4, Cl2, and SiH2Cl2. Furthermore, the modifying step S100 may be performed at a temperature ranging from −20° C. to 150° C. According to the embodiment of the present disclosure, the modified gas supplied in the modifying step S100 may be supplied in a gaseous state or a plasma state, depending on the type of metal oxide film.

The primary purging step S200 is performed by supplying the purging gas from the third gas supply unit 1260 and removing the modified gas remaining in the processing space in the first chamber 220. The purging gas may be supplied after the modified gas supply is stopped. As the purging gas is supplied, the modified gas, which is supplied in the modifying step S100 and remains in the processing space in the chamber 220, and reaction byproducts may be removed from the processing space. The purging gas may be inert gas such as argon (Ar), helium (He), nitrogen (N2), etc.

The adsorbing step S300 is performed by supplying the adsorbed gas from the second gas supply unit 1240 into the processing space of the first chamber 220 and allowing the adsorbed gas to be adsorbed on the surface of the metal oxide film modified in the modifying step S100. The adsorbed gas may be physically adsorbed on the surface layer of the modified metal oxide film. Thereafter, the modified metal oxide film is not etched by ligand substitution reaction, and the binding energy can be weaker than before the adsorbing step S300 is performed. According to the embodiment of the present disclosure, the adsorbed gas may be a β-diketone-based precursor. The β-diketone-based precursor may be one of a group consisting of Hfac (hexafluoroacetylacetone), Tfac (trifluoroacetyl chloride), and acac (acetylacetone), but is not limited thereto. The β-diketone-based precursor may react with the surface of the modified metal oxide film and then volatilize. The adsorbing step S300 may be performed at a temperature ranging from −20° C. to 150° C.

The secondary purging step S400 is performed by supplying the purging gas from the third gas supply unit 1260 and removing the adsorbed gas remaining in the processing space in the first chamber 220. The adsorbed gas may be supplied after the modified gas supply is stopped. As the purging gas is supplied, the adsorbed gas, which is supplied in the adsorbing step S300 and remains in the processing space in the chamber 220, and reaction byproducts may be removed from the processing space. The purging gas may be inert gas such as argon (Ar), helium (He), nitrogen (N2), etc.

The etching step S500 may be performed by supplying heat into the processing space in the second chamber 240 and atomic layer-based etching the metal oxide film. The metal oxide film may be atomic layer-based etched by supplying inert gas from a gas supply unit 2300 into the processing space of the chamber 240 and simultaneously supplying heat to the substrate W using the heating unit 2200. In the etching step S500, the surface layer of the metal oxide film on which the adsorbed gas is adsorbed at the adsorbing step S300. According to the embodiment of the present disclosure, the metal oxide film may be etched by using a halogen lamp and supplying heat ranging from 300° C. to 450° C. to the substrate.

The third purging step S600 is performed by supplying the purging gas from the gas supply unit 2300 of the second chamber 240 and removing etching byproducts remaining in the processing space in the chamber 240. The purging gas may be supplied after the heat supply is stopped. As the purging gas is supplied, etching byproducts remaining in the processing space in the chamber 240 may be removed from the processing space. The purging gas may be inert gas such as argon (Ar), helium (He), nitrogen (N2), etc.

The following [Table 1] presents the experiment results of examples and comparative examples of the present disclosure.

The experiment is performed using the silicone substrate on which a ZrO2 film is formed, and measurement data of the surface roughness of the substrate after the experiment, and the types and density of halogen elements remaining on the surface of the substrate.

TABLE 1

| | | | Reference | | | | Comparative | Comparative | Comparative |
|---|---|---|---|---|---|---|---|---|---|
| | | | example | Example 1 | Example 2 | Example 3 | example 1 | example 2 | example 3 |
| Film to be etched | | | ZrO₂ | ZrO₂ | ZrO₂ | ZrO₂ | ZrO₂ | ZrO₂ | ZrO₂ |
| ALE | Modifying | Modifying | — | HBr | HBr | HBr | NF₃ | NF₃ | NF₃ |
| | step | gas | | | | | | | |
| | | Reaction | — | Gas | Gas | Gas | Plasma | Plasma | Plasma |
| | | species | | | | | | | |
| | Adsorbing step | Precursor | — | — | Hfac | Hfac | — | Hfac | Hfac |

| | | | | | | | | |
|---|---|---|---|---|---|---|---|---|
| | Modifying · Adsorbing | — | — | 50 | 200 | — | 50 | 200 |
| | temperature | | | | | | | |
| | (° C.) | | | | | | | |
| | Etching temperature | — | — | 350 | 350 | — | 350 | 350 |
| | (° C.) | | | | | | | |
| | Cycle times | — | 20 | 100 | 100 | 20 | 100 | 100 |
| | EPC | — | — | 0.13 | Not | — | 0.35 | 0.44 |
| | (A/cycle) | | | | etched | | | |
| Analysis | [Surface]Roughness | 1.26 | 1.36 | 1.25 | 2.65 | 9.49 | 2.98 | 13.38 |
| | (nm) | | | | | | | |
| | [Surface]Halogen | 0 | [Br]12.26 | [Br] 1.89 | [Br] 0.12 | [F]17.19 | [F]13.36 | [F]19.23 |
| | at. % | | | | | | | |

In example 1, the modifying step in which HBr gas is supplied to modify the surface of the substrate was performed 20 times. In this case, the surface roughness is 1.36 nm, and the halogen element remaining on the surface of the substrate was detected as bromine (Br) and 12.26%.

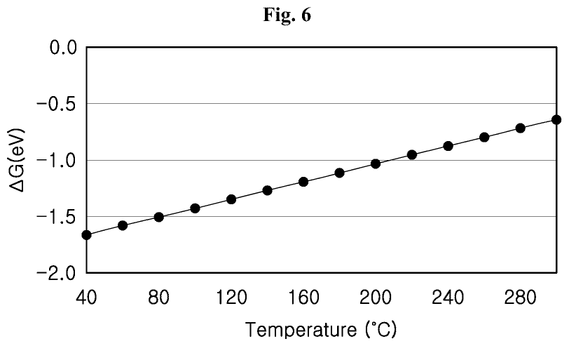

FIG. 6 is a view showing the thermodynamic analysis result of the reaction between ZrO2 and HBr at temperatures when the modifying step is performed.

Referring to FIG. 6, ZrO2 film and HBr react so that ZrBr4 or H2O may be generated (ZrO2+4HBr→ZrBr4+2(H2O)), and Gibbs free energy is reduced as the temperature is lowered, and this indicates that the reactivity between ZrO2 and HBr is predominant.

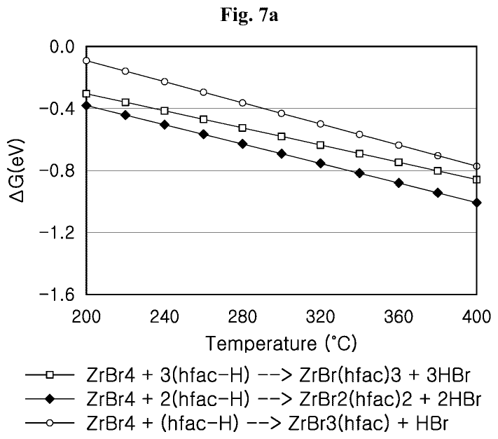

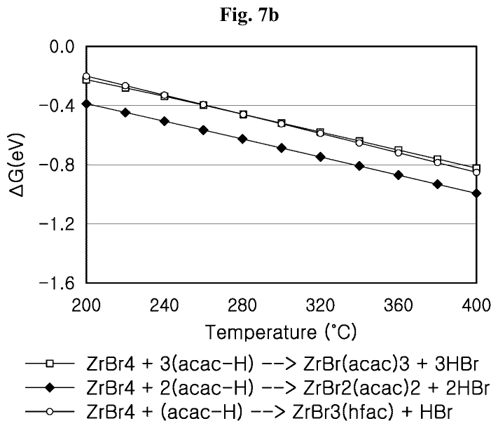

FIG. 7 is a view showing the thermodynamic analysis result of the precursor reaction at temperatures, by using example 1. Based on the results of FIG. 6, the reaction between the modified substrate and a precursor is checked. FIG. 7A is a view showing the reaction results of a HFC precursor, and FIG. 7B is the reaction result of an acac precursor.

In FIG. 7A, hfac was supplied to ZrBr4 that is the modified substrate. As a result, ZrBr4 film and hfac react so that ZrBr(hfac) and HBr may be generated (ZrBr4+3(hfac-H)→ZrBr(hfac)3+3HBr, ZrBr4+2(hfac-H)→ZrBr2(hfac)2+2HBr, ZrBr4+(hfac-H)→ZrBr3(hfac)+HBr), and Gibbs free energy is reduced as the temperature is increased, and this indicates that the reactivity between modified ZrBr4 and hfac is predominant.

In FIG. 7B, acac was supplied to ZrBr4 that is the modified substrate. As a result, ZrBr4 film and acac react so that ZrBr(acac) and HBr may be generated (ZrBr4+3(acac-H)→ZrBr(acac)3+3HBr, ZrBr4+2(acac-H)→ZrBr2(acac)2+2HBr, ZrBr4+(acac-H)→ZrBr3(acac)+HBr), and Gibbs free energy is reduced as the temperature is increased, and this indicates that the reactivity between modified ZrBr4 and acac is predominant.

In example 2 and example 3, the process of supplying HBr gas and modifying the surface of the substrate and allowing hfac to be adsorbed on the surface of the substrate modified by supplying Hfac and then supplying heat and etching the substrate on which Hfac was adsorbed was performed 100 times. At this point, in example 2, the temperature of the modifying and adsorbing processes is 50° C., but in example 3, the temperature of the modifying and adsorbing processes is 200° C. In example 2, ZrO2 is etched, and the surface roughness of the substrate is 1.25 nm, and the halogen element remaining on the surface of the substrate is bromine (Br), and was detected at 1.89%. In example 3, ZrO2 is not etched, and the surface roughness of the substrate is 2.65 nm, and the halogen element remaining on the surface of the substrate is bromine (Br), and was detected at 0.12%.

In comparative example 1, the modifying step in which plasma-ionized HBr is supplied to modify the surface of the substrate was performed 20 times. At this point, the surface roughness of the substrate is 9.49 nm, and the halogen element remaining in the surface of the substrate was fluorine (F) and detected at 17.19%.

In comparative example 2 and comparative example 3, the process of plasma-ionizing NF3 and modifying the surface of the substrate and allowing Hfac to be adsorbed on the surface of the substrate modified by supplying Hfac and then supplying heat and etching the substrate on which Hfac was adsorbed was performed 100 cycles. At this point, in comparative example 2, the temperature of the modifying and adsorbing processes is 50° C., but in comparative example 3, the temperature of the modifying and adsorbing processes is 200° C. In both comparative example 2 and comparative example, ZrO2 was etched. At this point, in comparative example 2, the surface roughness of the substrate is 2.98 nm, and a halogen element remaining on the surface of the substrate was fluorine (F), and was detected at 13.36%. At this point, in comparative example 3, the surface roughness of the substrate is 13.38 nm, and a halogen element remaining on the surface of the substrate was fluorine (F), and detected at 19.23%.

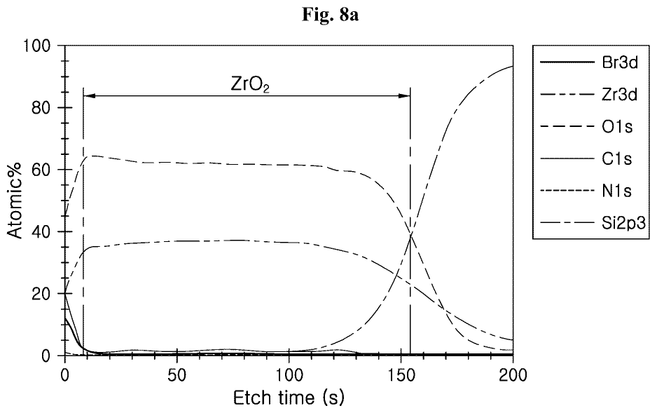

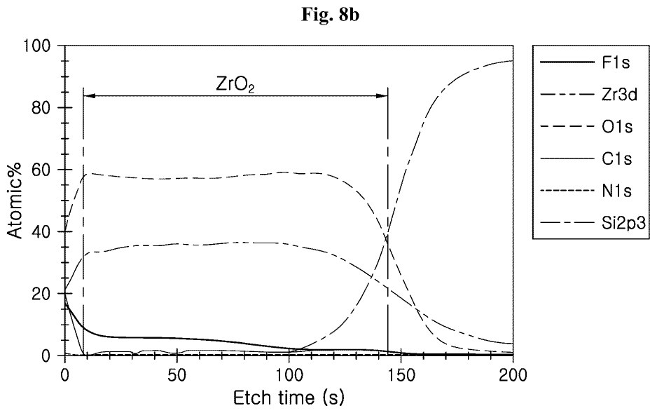

FIGS. 8A and 8B are views showing the result of the density of the modified gas detected from the internal space of ZrO2 of example 1 and comparative example 1. Referring to FIG. 8A, in example 1, bromine remained only on the surface of ZrO2, and was not detected in the internal space of ZrO2. Referring to FIG. 8B, in comparative example 1, fluorine was detected in the surface and the internal space of ZrO2, and the silicone substrate, and this causes defects in semiconductor devices.

Furthermore, as result of comparing example 1 and example 2, in example 1, in which only the modifying step was performed, bromine remaining on the surface of the substrate was detected at a high level, but in example 2, in which ZrO2 was etched in the atomic layer-based etching process, bromine remains on the surface of the substrate at a low level. However, in comparative example 1 and comparative example 2, where NF3 plasma is used, even when the modifying step or the atomic layer-based etching process is performed, fluorine remains on the surface of the substrate at a high level.

Examples are described with bromine-based gas used, but chloride-based gas may be used. Specifically, the radius of a fluorine atom is 50 μm, the radius of a chloride atom is 100 μm, and the radius of a bromine atom is 115 μm. The size of a fluorine atom is smaller than that of a chloride atom and a bromine atom, and the size of a chloride atom is not significantly different from the size of a bromine atom. Therefore, even when chloride-based gas is used, the result thereof may be similar to that of using bromine-based gas.

Furthermore, when bromine-based gas and chloride-based gas are used, the gas does not penetrate the internal space of the metal oxide film in the modifying step in comparison to the usage of fluorine-based gas, so that oxygen vacancy generated in the metal oxide film can be reduced.

As described above, the metal oxide film may be modified using bromine-based gas and chloride-based gas, and a β-diketone-based precursor is supplied to the surface of the modified metal oxide film, so that the precursor can be adsorbed on the surface of the modified metal oxide film. Thereafter, heat is supplied to the modified metal oxide film with the surface adsorbing the precursor, thereby atomic layer-based etching the metal oxide film. When the metal oxide film is modified using bromine-based gas, bromine-based gas is not detected from the internal space of the metal oxide film. This indicates that a bromine atom that is greater than a fluorine atom does not penetrate the internal space of the metal oxide film. Accordingly, the oxygen vacancy generated in the metal oxide film can be reduced, and damage to semiconductor devices can be prevented. Furthermore, the β-diketone-based precursor is volatilized after reacting with the surface of the modified metal oxide film, thereby preventing the generation of metallic and caustic byproducts. Therefore, the life cycle of the chamber can extend, and the manufacturing yield of semiconductor devices can also be improved.

Although the embodiments of the present disclosure have been disclosed for illustrative purposes, those skilled in the art will appreciate that various modifications, additions, and substitutions are possible, without departing from the scope and spirit of the present disclosure as disclosed in the accompanying claims. Therefore, the embodiments of the present disclosure are intended to described, without limiting the technical ideas of the present disclosure, and the technical ideas of the present disclosure are not limited by the embodiments. The scope of the present disclosure will be interpreted by the accompanying claims, and those skilled in the art should understand that all technical ideas within equivalent scope should be included in the scope of the present disclosure.

What is claimed is:

1. A substrate processing method for atomic layer-based etching a metal oxide film formed on a substrate, the method comprising:
supplying halogen-based modified gas into a processing space of a chamber where the substrate is disposed, and modifying the metal oxide film;
supplying adsorbed gas into the processing space and allowing the adsorbed gas to be adsorbed on a surface of the modified metal oxide film; and
supplying heat to the substrate on which the adsorbed gas is adsorbed, and etching the metal oxide film,
wherein the modified gas is bromine-based gas or chloride-based gas, and
the adsorbed gas is a β-diketone-based precursor.

2. The substrate processing method of claim 1, wherein a cycle comprising the modifying of the metal oxide film or the etching of the metal oxide film is repeated at least one time.

3. The substrate processing method of claim 1, wherein the metal oxide film is one of a group consisting of HfO2, ZrO2, BaO, TiO2, Ta2O5, La2O3, HZO, and IGZO.

4. The substrate processing method of claim 1, wherein the modified gas is one or a group consisting of HBr, Br2, BBr3, SiBr4, CBr4, CBr2Cl2, CBrCl3, SiCl4, CCl4, Cl2, and SiH2Cl2.

5. The substrate processing method of claim 4, wherein as the metal oxide film is modified using the modified gas, oxygen vacancies generated in the metal oxide film are reduced in comparison to usage of fluorine-containing modified gas.

6. The substrate processing method of claim 1, wherein the β-diketone-based precursor is one of a group consisting of Hfac, Tfac, and acac.

7. The substrate processing method of claim 6, wherein the β-diketone-based precursor prevents caustic byproducts from being generated in the chamber.

8. The substrate processing method of claim 1, wherein the modifying of the metal oxide film and the adsorbing of adsorbed gas on the metal oxide film are performed at a temperature ranging from −20° C. to 150° C.

9. The substrate processing method of claim 1, wherein the etching of the metal oxide film is performed at a temperature ranging from 300° C. to 450° C.

10. Semiconductor manufacturing equipment comprising:
an index block in which a substrate is stored;
a processing block comprising a first chamber and a second chamber to perform a process of processing the substrate;
a substrate transfer block comprising a substrate transfer robot that is used to remove or insert the substrate; and
a control device,
wherein the first chamber is a space where a metal oxide film is modified with modified gas, and adsorbed gas is adsorbed on the modified metal oxide film, and
the second chamber is a space where heat is supplied so as to atomic layer-based etch the metal oxide film on which the adsorbed gas is adsorbed.

11. The semiconductor manufacturing equipment of claim 10, wherein the first chamber comprises:
a substrate support unit for supporting the substrate; and
a gas supply unit for supplying the modified gas and the adsorbed gas to a processing space of the first chamber,
wherein the modified gas is bromine-based gas or chloride-based gas, and modifying of the metal oxide film is performed by supplying the modified gas and modifying the metal oxide film formed on the substrate, and
the adsorbed gas is a β-diketone-based precursor, and adsorbing of adsorbing gas is performed by supplying the adsorbed gas and allowing the adsorbed gas to be adsorbed on a surface of the modified metal oxide film.

12. The semiconductor manufacturing equipment of claim 10, wherein the modified gas is one of a group consisting of HBr, Br2, BBr3, SiBr4, CBr4, CBr2Cl2, CBrCl3, SiCl4, CCl4, Cl2, and SiH2Cl2.

13. The semiconductor manufacturing equipment of claim 10, wherein the adsorbed gas is one of a group consisting of Hfac, Tfac, and acac.

14. The semiconductor manufacturing equipment of claim 11, wherein the first chamber comprises a plasma generation unit to generate plasma in the first chamber.

15. The semiconductor manufacturing equipment of claim 11, wherein the substrate support unit comprises a cooling member to lower a temperature of the substrate to −20° C.

16. The semiconductor manufacturing equipment of claim 11, wherein the second chamber comprises:
a substrate support unit for supporting the substrate;
a gas supply unit for supplying gas to a processing space of the second chamber; and
a heating unit for supplying heat to the substrate, and
wherein etching of a substrate is performed by supplying heat to the substrate using the heating unit and etching the substrate on which the adsorbed gas is adsorbed on the surface of the modified metal oxide film.

17. The semiconductor manufacturing equipment of claim 16, wherein the heating unit is one of a group consisting of a halogen lamp, a microwave unit, a laser unit, and an infrared lamp.

18. The semiconductor manufacturing equipment of claim 16, wherein the heating unit supplies heat to the processing space of the second chamber and heats the substrate to a temperature ranging from 300° C. to 450° C., thereby atomic layer-based etching the substrate on which the adsorbed gas is adsorbed on the surface of the modified metal oxide film.

19. Semiconductor manufacturing equipment comprising:
an index block in which a substrate is stored;
a processing block comprising a first chamber and a second chamber to perform a process of processing the substrate;
a substrate transfer block comprising a substrate transfer robot that is used to remove or insert the substrate; and
a control device,
wherein the first chamber comprises:
a substrate support unit for supporting the substrate;
a gas supply unit for supplying modified gas and adsorbed gas into a processing space of the first chamber; and
a plasma generation unit for plasma-ionizing the supplied modified gas,
wherein the modified gas is bromine-based gas or chloride-based gas, and modifying of a metal oxide film is performed by supplying the modified gas to modify the metal oxide film formed on the substrate, and
the adsorbed gas is a β-diketone-based precursor, and adsorbing of adsorbed gas is performed by supplying the adsorbed gas so that the adsorbed gas is adsorbed on a surface of the modified metal oxide film,
the second chamber comprises:
a substrate support unit for supporting the substrate;
a gas supply unit for supplying gas to a processing space of the second chamber; and
a heating unit for supplying heat to the substrate,
wherein etching of a substrate is performed by supplying heat to the substrate using the heating unit, and by atomic layer-based etching the substrate on which the adsorbed gas is adsorbed on the surface of the modified metal oxide film, and
the modifying of the metal oxide film and adsorbing of adsorbed gas are performed at a temperature ranging from −20° C. to 150° C., and the etching of a substrate is performed at a temperature ranging from 300° C. to 450° C.

20. The semiconductor manufacturing equipment of claim 19, wherein the control device is configured to control the plasma generation unit, and the gas supply unit and the heating unit which are included in the first chamber and the second chamber so as to modify the metal oxide film in the first chamber, allow the precursor to be adsorbed on the surface of the modified metal oxide film, and atomic layer-based etch the substrate on which the precursor is adsorbed on the surface of the metal oxide film modified, in the second chamber.
